(19) United States
(12) Patent Application Publication
(10) Pub. No.: US 2009/0309026 A1
(43) Pub. Date: Dec. 17, 2009

(54) Optical sensor device having a lens system at least partially integrated into the unit housing

(76) Inventors: Hans-dieter Bothe, Seelze (DE); Heiko Freienstein, Weil der Stadt (DE); Steffen Abraham, Hildesheim (DE)

Correspondence Address: KENYON & KENYON LLP, ONE BROADWAY, NEW YORK, NY, 10004, US

(21) Appl. No.: 10/585,520

(22) PCT Filed: Nov. 12, 2004
(86) PCT No.: PCT/EP2004/052947

§ 371 Date: May 13, 2009

(30) Foreign Application Priority Data
Jan. 9, 2004 (DE) 10 2004 001 425.6

(51) Int. Cl. H01L 31/02; G02B 7/02

(52) U.S. Cl. 250/338.1; 250/552; 359/811

(57) ABSTRACT

An optical unit, having a sensor device in particular, including a housing enclosing same, a radiation-sensitive sensor surface, designed for detecting electromagnetic radiation from a frequency section, having a predefined width and position, of the spectral range including the near infrared range and/or the visible range, and a lens system. In order to reduce the cost and complexity for mounting a lens on the housing and to obtain a uniform housing surface on the object side, a part of the lens system acting as a lens on the object side or the entire lens system of the unit is designed as an integral component of the housing of the unit.

### FIELD OF THE INVENTION

The present invention is directed to an optical functional unit, including an optical functional element operating with a lens system and a housing enclosing same.

### BACKGROUND INFORMATION

Such units, in the form of an optical sensor device having a sensor surface and a lens system, for example, are known from the field of automobile technology. A sensor device is referred to as optical when it detects electromagnetic radiation from a frequency section of the visible (VIS) and/or the near infrared (NIR) spectrum range. The wavelengths of the radiation are approximately between 400 nm to 1,000 nm. Another example of such units is light fixtures having a light source, the light of which is emitted via a special lens system.

Optical sensor devices are used in a wide range of technology fields. Optical sensor devices are being used more frequently in motor vehicles in particular. They are used, for example, for detecting the surroundings or for sensing the passenger compartment of a motor vehicle.

An important component of an optical sensor device is its lens system acting as its “eye.” The radiation enters through the lens system and is refracted or focused according to the intended imaging conditions. The lens system is essentially made up of one or multiple lenses. In most of the presently known optical sensor devices, the lens system is a self-contained closed part which is mounted on or on the front of the housing of the sensor device. Appropriate mounting devices on the housing, such as threaded holders, are necessary for holding the lens system. The manufacture of the individual parts of the lens system and their connection to the housing of the sensor device entail additional complexity and expenditure. The lens systems protrude to the outside in most cases and are therefore conspicuous from the outside to the viewer. Edges and recesses in the unit housing are created due to the necessary apertures for the lens system. Dirt which tends to accumulate at these points is not able to be easily removed from these points. However, sensor devices are known in which the lens system does not protrude to the outside, but is situated behind a glass pane and is protected from outside effects. Known are, for example, configurations of optical sensor devices behind rear windows or, as described in Japanese Patent No. JP 03-273953, behind the glass of the headlights of a motor vehicle. However, an additional glass pane is used which is not a necessary component of the lens system. This results in additional complexity and higher costs. Moreover, each additional medium in the optical radiation path has an adverse effect on the image quality of the sensor device due to reflections, absorptions, and diffraction.

The sensor device described in German Patent Application No. DE 198 05 000 represents an improvement over the related art. The lens system or parts thereof are integral components of the windshield. The housing is situated directly behind the windshield. However, this particular design of the windshield including integrated lenses incurs great costs, and mounting the sensor housing on the flat pane is problematic.

### SUMMARY OF THE INVENTION

The present invention provides units in terms of more or less compact function units, including, for example, a multi-purpose optical sensor device or a light fixture in which the particular lens system is inserted into the self-contained closed unit in a simple and cost-effective manner. At least one optical lens on the object side, as a separate single part, and its mounting device are no longer necessary. For the present invention, a lens is considered optical when it acts as a lens for radiation from the VIS and/or NIR range.

The uniform housing surface on the object side according to the present invention is easy to clean and offers sufficient contamination protection. An interfering protrusion of the lens system is avoided. An additional pane in front of the lens system, which impairs the optical quality, is unnecessary.

According to an advantageous embodiment of the present invention, the sensor device is designed for use in a motor vehicle for monitoring the passenger compartment. In particular in motor vehicles, the optical sensor devices according to the present invention may be installed simply and cost-effectively in a manner which does not subsequently irritate the driver.

According to another advantageous embodiment of the present invention, the part of the lens system, integrated into the housing and acting as an optical lens, or the entire lens system, integrated into the housing, is designed to be transparent for the NIR range and non-transparent for the VIS range for a frequency section of the electromagnetic radiation, predefined with respect to position and width. Images of objects illuminated by radiation from the NIR range and those from the VIS range are very similar. The absorption and reflection behaviors do not show any important differences. A space may thus be monitored via video using NIR radiation alone. Due to the fact that the lens system is non-transparent to the human eye, sensing may occur without the observed person being aware of it and feeling disturbed. From the outside, the person sees a uniform, non-transparent housing surface.

According to another, improved embodiment of the sensor device according to the present invention, the housing part, at least partially including the lens system, is manufactured using injection-molding technology. This is a particularly simple and cost-effective way to further reduce the complexity and costs for manufacturing and integrating the lens system in particular.

Another advantageous embodiment of the present invention provides for the design of the housing part, at least partially including the lens system, to be a component of an interior lining of a motor vehicle, thereby making the units what is referred to as “sub-units.” This eliminates manufacturing costs for both the interior lining and the housing part of the sensor device on the object side. The lens system of the device according to the present invention is integrated into the interior lining without protruding conspicuously and is not noticed in a disturbing way by the vehicle's passengers. This design advantageously allows cost-effective and inconspicuous sensing of the vehicle's passenger compartment, e.g., for controlling restraint systems.

The sensor device according to the present invention is particularly suitable for using video to monitor systems, such as range video systems and camera systems, particularly spatially detecting stereo camera systems. Such systems are particularly well suited for use in motor vehicles.

Such camera systems often require their “own,” “active” lighting, which is frequently sensibly integrated into the camera. In order for the light source to optimally light the scene (or section of the scene), an appropriate lens system, made up of one or multiple optically acting lenses, may be mounted in front of the light source, according to the present invention. The light source may be light bulbs, for example, or LEDs, laser diodes, or IREDs (IR emitting diodes) which are associated with other advantageous effects. The enclosure according to the present invention may also, according to a simple variant, have no optical effect and may simply be used for protecting and concealing the light source. In other words, the housing may not only be used as an optically acting part of the lens system in front of an image recorder, but may also be used, alone or in connection with other optical functional elements, as an optically acting or merely as a concealing part in front of the light source. That is, the light source as a first optical functional element may also be situated in the same housing as the sensor device as a second optical functional element.

### BRIEF DESCRIPTION OF THE DRAWINGS

FIG. 1 shows a schematic cross section of an exemplary embodiment of the optical sensor device according to the present invention.

FIG. 2 shows a cross section of a part of the housing, acting as an optical lens, of an exemplary embodiment of the sensor device according to the present invention.

FIG. 3 shows a schematic representation of an exemplary application of a video-based system including the optical sensor device according to the present invention.

### DETAILED DESCRIPTION

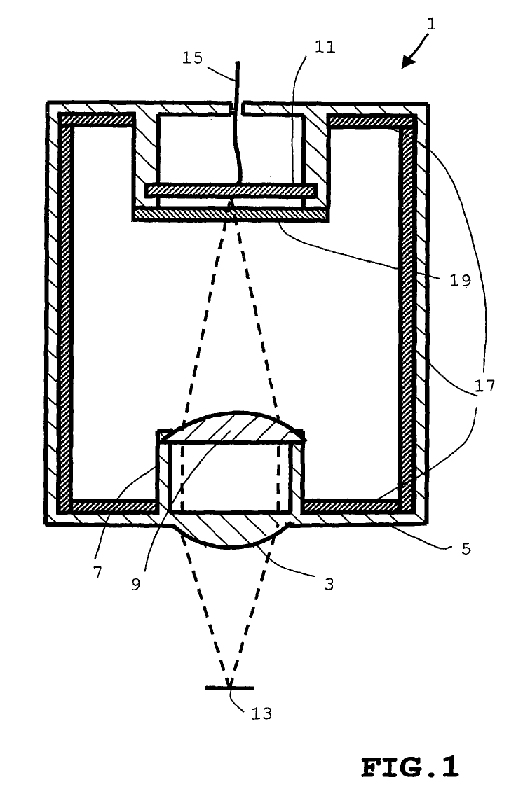

FIG. 1 shows a schematic cross section of an example of optical sensor device 1 according to the present invention. Optical sensor device 1 is enclosed by a unit housing 5. This housing 5 is made up of molded parts via injection molding, for example. Manufacture in a different way is likewise possible. According to the present invention, unit housing 5 has a lens-shaped convexity 3 on the object side. It is part of the lens system of sensor device 1 including an additional lens 9. The lens system is not necessarily made up of two parts acting as lenses, but may be designed differently as a function of the optical requirements and to include one or multiple optical elements. With a particular further design, lens-shaped convexity 3 of unit housing 5 may be sufficient as a lens system for an appropriate use of sensor device 1.

According to the present invention, in particular in the area of lens-shaped part 3, unit housing 5 is made of a material which is transparent for electromagnetic radiation in a frequency range for NIR and/or VIS. Dyed plexiglass or a polycarbonate dyed for injection molding are preferable, for example. These materials are non-transparent to the human eye, but are transparent for radiation from the NIR range, so that the observer regards housing 5 as a common unit cover. The incident radiation is focused by lens system 3, 9 onto the side of sensor surface 11 which is sensitive to this radiation. Starting from an object point 13, a beam path is indicated by dashed lines. Sensor surface 11 is a CCD chip sensitive to NIR radiation, for example. The image information recorded by sensor surface 11 is conveyed in electronic form to image-processing or imaging system components via signal line 15, as is known from the related art.

In order to shield sensor surface 11 from radiation which penetrates housing 5 outside of lens-shaped convexity 3, housing 5 is provided on the inside with a shield 17 in these areas. This shield 17 is made of a material which is impermeable for radiation from the frequency range to which sensor surface 11 is sensitive.

Furthermore, a filter 19 is situated in the beam path between lens system 3, 9 and sensor surface 11. This filter is permeable only for radiation from a predefined, tightly limited frequency band in the NIR range, for example. TiO2 is used as the filter material, for example, which has a permeable frequency window of 40 nm band width in the NIR range.

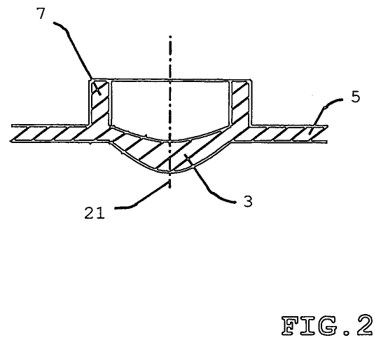

FIG. 2 schematically shows a cross section of a part 3 of housing 5, acting as an optical lens, as an example of optical sensor device 1 according to the present invention. Housing 5 is transparent for NIR radiation. It is spherically convex in center section 3 on the object side. On the inside in comparison, housing 5 is only slightly convex in this section 3 in the direction of the object, so that the diameter of the housing wall increases toward the center. This part 3, acting as an optical lens, forms a lens which is suitable for wide angle shooting. Optical axis 21 runs perpendicular to the surface of housing 5 through the center of section 3 designed as a lens. Auxiliary edge 7, which encloses section 3 from the inside, is used for connecting additional elements of the lens system or other components of the sensor device at a fixed distance.

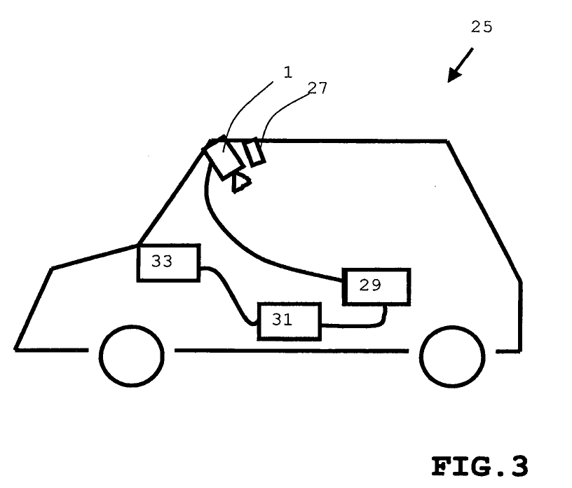

FIG. 3 shows a schematic representation of a video-based system, which includes optical sensor device 1 according to the present invention, for monitoring the passenger compartment of a motor vehicle 25. This monitoring is used for controlling restraint systems such as airbags.

The passenger compartment of motor vehicle 25 is lighted by an NIR lamp 27. This is, for example, a field of LEDs emitting in the NIR range. The passenger compartment of the motor vehicle, lighted in this way, is recorded by a recording system which includes one or multiple optical sensor devices 1 which are sensitive to this frequency range. The recording system detects the objects in the passenger compartment of the motor vehicle three-dimensionally and is designed as a range video system or a stereo camera system, for example.

The part of the housing of optical sensor device 1 including the lens system on the object side preferably forms a part of the interior lining of motor vehicle 25. Sensor device 1 is connected to a control unit 29 of the recording system. Control unit 29 regulates the functions, which primarily include the alignment and the sensitivity of sensor device 1, and receives the image signals. It is connected to control unit 31 of the restraint system. This analyzes the transmitted image data with regard to type, position, and distance of the object in front of airbag 33. If, in the event of an accident, for example, no living object is detected in front of airbag 33, control unit 31 does not trigger the airbag. However, if a person is situated in the seat in front of airbag 33, the airbag is triggered more or less powerfully depending on the distance of the person from the deployment range of the airbag. If the person is situated very close to the deployment range, triggering of airbag 33 is attenuated. This reduces the risk of injury when the airbag is triggered.

Although the present invention is described above on the basis of preferred exemplary embodiments, it is not restricted thereto, but is modifiable in numerous ways.

The optical sensor device according to the present invention may be used in banks for surveying the teller area, for example. The customer does not recognize the optical sensor device as such and is not disturbed by the camera surveillance.

1-12. (canceled)

13. An optical functional unit comprising:
an optical functional element;
a housing enclosing the optical functional element; and
a lens system, the optical functional element operating with the lens system, wherein one of (a) an object-side part of the lens system acting as an optical lens and (b) the entire lens system of the unit is an integral component of the housing of the unit.

14. The unit according to claim 13, wherein the unit is a sensor device and the functional element includes a radiation-sensitive sensor surface, which is designed to detect electromagnetic radiation from a frequency section of the spectral range including at least one of a near infrared range and a visible range, the frequency section having a predefined width and position.

15. The unit according to claim 13, wherein the unit is a subunit for use in a passenger compartment of a motor vehicle.

16. The unit according to claim 13, wherein the one of (a) the part of the lens system acting as an optical lens and integrated into the housing and (b) the entire lens system integrated into the housing is transparent to a frequency section, whose position and width are predetermined, and which is of electromagnetic radiation from a near infrared range, and is opaque to a visible range.

17. The unit according to claim 13, wherein a housing part containing at least part of the lens system is made using injection molding technology.

18. The unit according to claim 13, wherein a housing part containing at least part of the lens system is part of an interior lining of a motor vehicle.

19. The unit according to claim 13, wherein the functional element includes an artificial light source.

20. The unit according to claim 19, wherein the light source is a light emitting diode.

21. The unit according to claim 19, wherein the light source is a diode emitting infrared light.

22. A housing for an optical unit comprising:
a housing unit enclosing an optical functional element, the optical functional element operating with a lens system, wherein one of (a) an object-side part of the lens system acting as an optical lens and (b) the entire lens system is an integral component of the housing unit.

23. A range video system comprising an optical sensor device, the optical sensor device including:
an optical functional element;
a housing enclosing the optical functional element; and
a lens system, the optical functional element operating with the lens system, wherein one of (a) an object-side part of the lens system acting as an optical lens and (b) the entire lens system of the device is an integral component of the housing of the device.

24. The range video system according to claim 23, wherein the system is used in a motor vehicle.

25. A camera system comprising an optical sensor device, the optical sensor device including:
an optical functional element;
a housing enclosing the optical functional element; and
a lens system, the optical functional element operating with the lens system, wherein one of (a) an object-side part of the lens system acting as an optical lens and (b) the entire lens system of the device is an integral component of the housing of the device.

26. The camera system according to claim 25, wherein the camera system is a stereo camera system.

27. The camera system according to claim 25, wherein the system is used in a motor vehicle.
